(19) United States
(12) Patent Application Publication
(10) Pub. No.: US 2024/0030874 A1
(43) Pub. Date: Jan. 25, 2024

(54) AMPLIFIER ASSEMBLY AND PHASE SHIFTING METHOD

(71) Applicant: SMARTER MICROELECTRONICS (GUANG ZHOU) CO., LTD., Guangzhou (CN)

(72) Inventors: Yangyang PENG, Guangzhou (CN); Ping LI, Guangzhou (CN); Yang LI, Guangzhou (CN)

(73) Assignee: SMARTER MICROELECTRONICS (GUANG ZHOU) CO., LTD., Guangzhou (CN)

(21) Appl. No.: 18/479,104

(22) Filed: Oct. 1, 2023

Related U.S. Application Data
(63) Continuation of application No. PCT/CN2022/121017, filed on Sep. 23, 2022.

(30) Foreign Application Priority Data
Sep. 23, 2021 (CN) 202111116040.9

(51) Int. Cl. H03F 1/02; H03F 3/24; H03F 3/45; H03F 1/56

(52) U.S. Cl. CPC H03F 1/0294; H03F 3/245; H03F 3/45475; H03F 1/565; H03F 2200/451

(57) ABSTRACT

An amplifier assembly includes an orthogonal signal generator, an adder and an amplification circuit. An output end of the orthogonal signal generator is connected with an input end of the adder, and the orthogonal signal generator is configured to generate an orthogonal signal. An output end of the adder is connected with an input end of the amplification circuit, and the adder is configured to vector-synthesize the orthogonal signal to output a first signal. The amplification circuit is configured to amplify a power of the first signal and compensate a phase of the first signal to output a second signal.

### CROSS-REFERENCE TO RELATED APPLICATIONS

This is a continuation of International Application No. PCT/CN2022/121017 filed on Sep. 23, 2022, which claims priority to Chinese Patent Application No. 202111116040.9 field on Sep. 23, 2021. The disclosures of the above-referenced applications are hereby incorporated by reference in their entirety.

### BACKGROUND

In some implementations, since an adder of a phase shifter brings out different gains for different phases, it is necessary to control the gain of an amplifier in case that a downstream amplification circuit of the adder performs power amplification. The insertion phase of the amplification circuit varies with the gain under different gain, which will significantly affect the phase shifting accuracy.

### SUMMARY

The disclosure relates to the technology of phase shifter, in particular to an amplifier assembly and a phase shifting method.

Embodiments of the disclosure are intended to provide an amplifier assembly and a phase shifting method.

In the first aspect, the embodiments of the disclosure provide an amplifier assembly. The amplifier assembly includes a orthogonal signal generator, an adder and an amplification circuit; an output end of the orthogonal signal generator is connected with an input end of the adder, and the orthogonal signal generator is configured to generate an orthogonal signal; an output end of the adder is connected with an input end of the amplification circuit, and the adder being configured to vector-synthesize the orthogonal signal to output a first signal; the amplification circuit is configured to amplify a power of the first signal and compensate a phase of the first signal to output a second signal.

In an embodiment, the amplification circuit includes an amplifier and a phase compensation circuit. The amplifier is configured to amplify the power of the first signal, and the phase compensation circuit is configured to compensate the phase of the first signal.

In an embodiment, an input end of the phase compensation circuit is connected with the output end of the adder, and an output end of the phase compensation circuit is connected with the amplifier to output the phase-compensated first signal.

In an embodiment, an input end of the amplifier is connected with the output end of the adder, and an output end of the amplifier is connected with an input end of the phase compensation circuit to output the amplified first signal.

In an embodiment, a compensation phase of the phase compensation circuit is adjustable based on a gain and/or an output power of the amplifier.

In an embodiment, the phase compensation circuit has a compensation structure of at least one of “pi (π) type”, “T type” and “L type”.

In an embodiment, the amplifier assembly further includes a first isolation circuit having an input end connected with an output end of the amplification circuit, and being configured to isolate the output end of the amplification circuit to isolate an interference of a downstream circuit of the amplification circuit to the amplification circuit.

In an embodiment, the amplifier assembly further includes a second isolation circuit. An input end of the second isolation circuit is connected with the output end of the adder, and an output end of the second isolation circuit is connected with the input end of the amplification circuit; the second isolation circuit is configured to isolate the output of the adder.

In an embodiment, the amplification circuit further includes an impedance matching circuit. The impedance matching circuit is configured to impedance-match an input impedance and/or an output impedance and/or an inter-stage impedance of the amplifier.

In an embodiment, the phase compensation circuit includes at least one element selected from an inductor, a capacitor and a switching tube.

In an embodiment, the amplifier is a differential amplifier.

In the second aspect, the embodiments of the disclosure provide a phase shifting method, which includes the following operations.

An orthogonal signal is generated by an orthogonal signal generator.

The orthogonal signal is vector-synthesized by an adder to output a first signal.

A power of the first signal is amplified and a phase of the first signal is compensated by an amplification circuit to output a second signal.

In the third aspect, the embodiments of the disclosure provide another phase shifting method, which includes the following operations.

A preset phase shift angle is acquired.

A first control signal and a second control signal are generated based on the preset phase shift angle; the first control signal is used for controlling an adder, and the second control signal is used for controlling an amplification circuit.

An orthogonal signal generated by an orthogonal signal generator is vector-synthesized through controlling the adder based on the first control signal to output a first signal by the adder

A power of the first signal is amplified and a phase of the first signal is compensated through controlling the amplification circuit based on the second control signal to output a second signal by the amplification circuit.

In the embodiments of the disclosure, the orthogonal signal generator generates the orthogonal signal, and the adder performs the vector-synthesizing on the orthogonal signal to output the first signal. The amplification circuit performs the power amplification and the phase compensation on the first signal, and outputs the second signal. The output second signal is the phase compensated in-phase signal. That is, the amplification circuit can perform the power amplification and the phase compensation on the first signal, thereby reducing the influence on the phase shifting accuracy caused by the change of the insertion phase of the amplification circuit under different gains.

In the fourth aspect, the embodiments of the disclosure provides a computer program product including a computer-readable code, in which the operations of the phase shifting method of the above third aspect are performed by a controller of the amplifier assembly when that the computer-readable code is executed in the amplifier assembly.

It should be understood that the above general description and the following detailed description are exemplary and explanatory only and are not limiting to the disclosure.

Other features and aspects of the disclosure will become apparent from the following detailed description of exemplary embodiments with reference to the drawings.

### BRIEF DESCRIPTION OF THE DRAWINGS

The drawings, which are incorporated in and constitute a part of the specification, illustrate embodiments consistent with the disclosure and together with the description serve to explain the technical solution of the disclosure.

FIG. 1 is a component circuit diagram of an active phase shifter in some implementations.

FIG. 2 is a schematic diagram of the component structure of an amplifier assembly provided by the embodiments of the disclosure.

FIG. 3 is a schematic diagram of the component structure of another amplifier assembly provided by the embodiments of the disclosure.

FIG. 4 is a schematic diagram of the component structure of yet another amplifier assembly provided by the embodiments of the disclosure.

FIG. 5 is an implementation flowchart of a phase shifting method provided by the embodiments of the disclosure.

FIG. 6 is an implementation flowchart of another phase shifting method provided by the embodiments of the disclosure.

FIG. 7 is an implementation flowchart of yet another phase shifting method provided by the embodiments of the disclosure.

FIG. 8 is an implementation flowchart of yet another phase shifting method provided by the embodiments of the disclosure.

FIG. 9 is an implementation flowchart of another phase shifting method provided by the embodiments of the disclosure.

FIG. 10A is a component schematic diagram of a phase compensation unit provided by embodiments of the disclosure.

FIG. 10B is a schematic diagram of the component structure of a phase compensation unit provided by embodiments of the disclosure.

FIG. 10C is a schematic diagram of the component structure of another phase compensation unit provided by embodiments of the disclosure.

FIG. 10D is a schematic diagram of the component structure of yet another phase compensation unit provided by embodiments of the disclosure.

FIG. 10E is a circuit diagram of an phase compensation unit provided by embodiments of the disclosure.

FIG. 11 is a component circuit diagram of an active phase shifter provided by embodiments of the disclosure.

Specific embodiments of the disclosure have been shown by the above drawings and will be described in more detail below. These drawings and descriptions are not intended in any way to limit the scope of the concept of the disclosure but to illustrate the concepts of the disclosure for those skilled in the art by reference to specific embodiments.

### DETAILED DESCRIPTION

The disclosure will be further described in further detail below with reference to the drawings and embodiments. It should be understood that the embodiments provided herein are intended to be explanatory only and are not intended to limit the disclosure. In addition, the embodiments provided below are a part of embodiments for implementing the disclosure, not all of the embodiments. The technical solutions described in the embodiments of the disclosure can be implemented in any combination without conflict.

It should be noted that, in the embodiments of the disclosure, terms “include”, “comprise” or any other variation thereof are intended to encompass non-exclusive inclusion, so that a method or equipment that includes a series of elements includes not only those explicitly recorded elements but also other elements that are not explicitly listed, or also elements inherent to implementation of a method or an equipment. In the absence of further limitations, an element defined by the phrase “including a . . . ” does not preclude the existence of another relevant elements (for example, an operation in the method, or a unit in equipment, such as part of the circuit, part of processor, and part of program or software) in the method or equipment in which it is included.

The term “and/or” herein is merely used for describing an association relationship of associated objects, indicating that there can be three relationships. For example, for the expression “U and/or W”, it may refer to three situations, i.e., U alone, both U and W, and W alone. In addition, the term “at least one” herein means any one or any combination of at least two of listed items. For example, for expressing “including at least one of U, W, V”, it may refer to any one or more selected from the group consisting of U, W, and V.

Phase shifter is a device configured to generate multi-phase signals, which is widely used in radio frequency systems. The phase shifter can be mainly divided into active phase shifter and passive phase shifter. The active phase shifter is characterized by small area, flexibility and controllability, and in that it can generate gain, but its linearity is limited. The passive phase shifter is characterized by stable phase, high linearity, but large area and some loss.

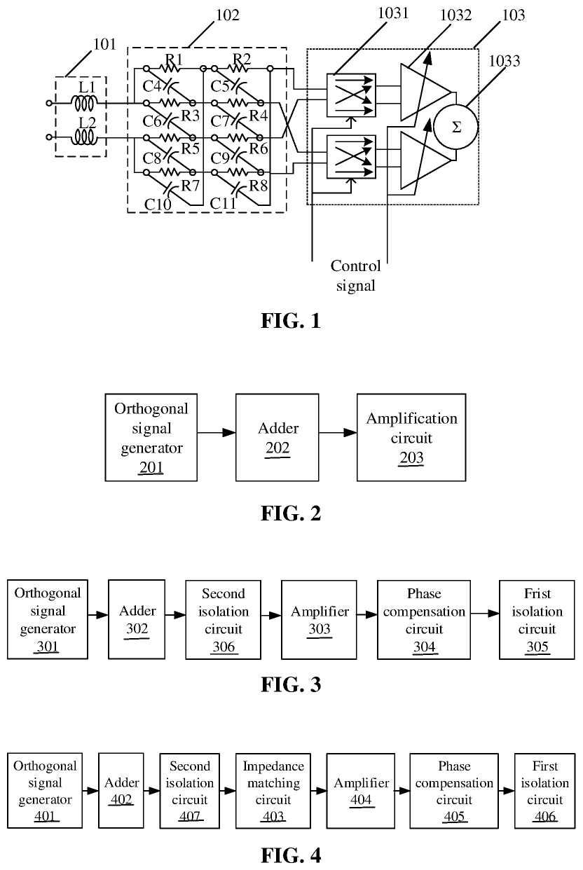

FIG. 1 is a component circuit diagram of an active phase shifter in some implementations. As shown in FIG. 1, the active phase shifter includes an inter stage matching network (IMN) 101, a poly phase filter (PPF) 102 and an analog adder 103 that are sequentially connected. Herein, the differential radio frequency signal is input to the input end of the IMN 101. The input differential radio frequency signal is network matched by IMN 101, and the network matched differential radio frequency signal is input to the PPF 102. Four orthogonal signals (two positive output ends I+, Q+, and two negative output ends I−, Q−) with the same amplitude and 90-degree phase spacing are generated by the PPF 102, and are input to the analog adder 103. The analog adder 103 performs vector composing on the four orthogonal signals with the same amplitude and 90-degree phase spacing in response to an external control signal, and outputs a radio frequency signal to a downstream amplifier.

Here, the IMN 101 includes a first inductor L1 and a second inductor L2. L1 and L2 are connected in series to the input end and the input end of the PPF 102, respectively. The PPF 102 is a two-order RC filter. The analog adder 103 includes an orthogonal path selecting unit 1031, a variable gain amplifier (VGA) 1032 and an adder 1033 that are connected in sequence.

It can be understood that the two-order RC filter includes eight resistors R1 to R8 and eight capacitors C4 to C11. Herein, the series branch formed by connecting R1 and R2 in series is connected between the input end and the output end (I+) of the two-order RC filter; the series branch formed by connecting R3 and R4 in series is connected between the input end and the output end (Q+) of the two-order RC filter; the series branch formed by connecting R5 and R6 in series is connected between the input end and the third output end (I−) of the two-order RC filter; the series branch formed by connecting R7 and R8 in series is connected between the input end and the fourth output end (Q−) of the two-order RC filter; C4 is connected across both ends of R3, and the positive electrode of C4 is connected to the input end; the negative electrode of C5 is connected to the output end, and the positive electrode of C5 is connected to the common node of R1 and R2; the positive electrode of C6 is connected to the input end, and the negative electrode of C6 is connected to the common node of R5 and R6; the negative electrode of C7 is connected to the third output end, and the positive electrode of C7 is connected to the common node of R3 and R4; C8 is connected across both ends of R7, and the positive electrode of C8 is connected to the input end; the negative electrode of C9 is connected to the fourth output end, and the positive electrode of C9 is connected to the common node of R5 and R6; the positive electrode of C10 is connected to the input end, and the negative electrode of C10 is connected to the common node of R1 and R2; the negative electrode of C11 is connected to the output end, and the positive electrode of C11 is connected to the common node of R7 and R8.

In some implementations, since the adder brings out different gains for different phase-shifting phases, it is necessary to control the gain of the amplification circuit in case of subsequent power amplification through the amplification circuit. The insertion phase of the amplification circuit varies with the gain of the amplification circuit under different gain (the relative phase shift of the amplifier at the specified frequency), which will significantly affect the phase shifting accuracy.

Based on the above problem, the embodiments of the disclosure provide an amplifier assembly. As shown in FIG. 2, the amplifier assembly includes an orthogonal signal generator 201, an adder 202, and an amplification circuit 203.

The output end of the orthogonal signal generator 201 is connected with the input end of the adder 202, and the orthogonal signal generator 201 is configured to generate an orthogonal signal.

The output end of the adder 202 is connected with the input end of the amplification circuit 204, and the adder 202 is configured to vector-synthesize the orthogonal signal to output a first signal.

The amplification circuit 203 is configured to amplify a power of the first signal and compensate a phase of the first signal to output a second signal.

In some possible embodiments, the orthogonal signal generated by the orthogonal signal generator 201 may be four orthogonal signals (two positive output ends I+, Q+, and two negative output ends I−, Q−) with the same amplitude and 90-degree phase spacing. The orthogonal signal generator 201 may be any generator capable of generating four orthogonal signals (two positive output ends I+, Q+, and two negative output ends I−, Q−) with the same amplitude and 90-degree phase spacing. For example, the orthogonal signal generator 201 may be a two-order RC filter.

In other embodiments, the orthogonal signal may also include multiple sub-signals, for example, 8 sub-signals. The phase difference among multiple sub-signals may also be other angles, such as 45 degrees.

In one possible embodiment, the amplifier assembly may also include a controller. The controller may be at least one of an application specific integrated circuit (ASIC), a digital signal processor (DSP), a digital signal processing device (DSPD), a programmable logic device (PLD), FPGA, a central processing unit (CPU), a controller, a microcontroller and a microprocessor. The controller can generate a first control signal for controlling the adder and a second control signal for controlling the amplification circuit, both corresponding to the preset phase shift angle. The preset phase shift angle may be determined according to the application scenario of the phase shifter. For example, in some application scenarios where the phase shifter needs to be shifted by 30° (degrees), the corresponding preset phase shift angle is 30°.

It could be understood that both the first control signal and the second control signal may be a switching signal for turning on or off the switching tube. For example, both of the first control signal and the second control signal may be a voltage control signal of +12V (volts) or a voltage control signal of 0V.

In one possible embodiment, the amplification circuit 204 may include an amplifier and a phase compensation circuit for compensating the insertion phase of the amplifier. The amplifier is configured to amplify the power of the first signal; and the phase compensation circuit is configured to compensate the phase of the first signal.

In one possible embodiment, the input end of the phase compensation circuit is connected with the output end of the adder, and the output end of the phase compensation circuit is connected with the amplifier to output the phase-compensated first signal.

In one possible embodiment, the input end of the amplifier is connected with the output end of the adder, and the output end of the amplifier is connected with the input end of the phase compensation circuit to output the amplified first signal.

In one possible embodiment, the compensation phase of the phase compensation circuit is adjustable based on the gain and/or output power of the amplifier.

In one possible embodiment, the phase compensation circuit has a compensation structure of at least one of “pi (π) type”, “T type” and “L type”.

In the embodiments of the disclosure, the orthogonal signal generator generates the orthogonal signal; the controller generates a first control signal for controlling the adder and a second control signal for controlling the amplification circuit based on a preset phase shift angle; the adder performs the vector-synthesizing on the orthogonal signal based on the first control signal to output the first signal; the amplification circuit performs the power amplification and phase compensation on the first orthogonal signal based on the second control signal to output the second signal which is the phase-compensated signal. That is, different second control signals may be generated for different preset phase shift angles, and the amplification circuit can perform power amplification and phase compensation on the first signal based on the different second control signals, thereby reducing the influence on the phase shifting accuracy caused by the change of the insertion phase of the amplification circuit under different gains.

The embodiments of the disclosure provide another amplifier assembly. As shown in FIG. 3, the amplifier assembly may include an orthogonal signal generator 301, an adder 302, an amplifier 303, a phase compensation circuit 304, a first isolation circuit 305 and a second isolation circuit 306.

The output end of the orthogonal signal generator 301 is connected with the input end of the adder 302, and the orthogonal signal generator 301 is configured to generate an orthogonal signal.

The output end of the adder 302 is connected with the input end of the second isolation circuit 306, and the adder 302 is configured to vector-synthesize the orthogonal signal to output a first signal.

The output end of the second isolation circuit 306 is connected with the input of the amplifier 303, and the second isolation circuit 306 is configured to isolate the output end of the adder.

The output end of the amplifier 303 is connected with the input end of the phase compensation circuit 304, and the amplifier 303 is configured to amplify the power of the isolated first signal.

The output end of the phase compensation circuit 304 is connected with the first isolation circuit 305, and the phase compensation circuit is configured to perform phase compensation on the isolated and power amplified first signal to output a second signal.

The first isolation circuit 306 is configured to isolate the output end of the amplification circuit to isolate the interference of the downstream circuit of the amplification circuit to the amplification circuit.

In one possible embodiment, the amplifier assembly may further include controllers connected to the adder 302, the amplifier 303 and the phase compensation circuit 304, respectively. The controllers are configured to generate a first control signal, a first sub-control signal, and a second sub-control signal based on a preset phase shift angle, respectively. The first control signal is configured to control the adder 302, the first sub-control signal is configured to control the gain of the amplifier 303, and the second sub-control signal is configured to control the phase compensation angle of the phase compensation circuit 304.

The output end of the adder 302 is connected with the input end of the second isolation circuit 306, and the adder 302 is configured to perform vector composing, based on the first control signal, on the orthogonal signal to output the first signal.

The output end of the second isolation circuit 306 is connected with the input of the amplifier 303, and the second isolation circuit 306 is configured to isolate the output end of the adder.

The output end of the amplifier 303 is connected with the input end of the phase compensation circuit 304, and the amplifier 303 is configured to perform power amplification, based on the first sub-control signal, on the isolated first signal.

The output end of the phase compensate circuit 304 is connected with the first isolation circuit 305, and the phase compensation circuit is configured to perform phase compensation, based on the second sub-control signal, on the isolated and powder amplified first signal to output the second signal.

The first isolation circuit 305 is configured to isolate the output end of the amplification circuit to isolate the interference of the downstream circuit of the amplification circuit to the amplification circuit.

In one possible embodiment, the amplifier 303 includes a switching tube that can adjust the gain of the amplifier 303 in response to the first sub-control signal.

It could be understood that, the second sub-control signal may be a switching signal determined according to the insertion phase of the amplifier 303 under the preset phase shift angle.

In one possible embodiment, the phase compensation circuit 304 may perform phase compensation on the powder amplified first signal in response to the switching signal determined based on the insertion phase to obtain a third signal.

In embodiments of the disclosure, the second isolation circuit isolates the output end of the adder, and the amplifier perform power amplification on the isolated first signal. The phase compensation circuit performs phase compensation on the isolated and power amplified first signal. The first isolation circuit isolates the output end of the amplification circuit to isolate the interference of the downstream circuit of the amplification circuit to the amplification circuit. The obtained second signal has high isolation degree, and high phase shift accuracy.

FIG. 4 is a schematic diagram of the component structure of yet another amplifier assembly provided by the embodiments of the disclosure. As shown in FIG. 4, the amplifier assembly includes an orthogonal signal generator 401, an adder 402, an impedance matching circuit 403, an amplifier 404, a phase compensation circuit 405, a first isolation circuit 406 and a second isolation circuit 407.

The output end of the orthogonal signal generator 401 is connected with the input end of the adder 402, and the orthogonal signal generator 401 is configured to generate an orthogonal signal.

The output end of the adder 402 is connected with the input end of the second isolation circuit 407, and the adder 402 is configured to vector-synthesize the orthogonal signal to output a first signal.

The output end of the second isolation circuit 407 is connected with the input of the impedance matching circuit 403, and the second isolation circuit 407 is configured to isolate the output end of the adder.

The impedance matching circuit 403 is connected with the amplifier 404, and configured to perform impedance matching in response to input impedance and/or output impedance and/or an inter-stage impedance of the amplifier 404.

The output end of the amplifier 404 is connected with the input end of the phase compensation circuit 405, and the amplifier 404 is configured to perform power amplification, based on the adjusted impedance matching circuit 403, on the isolated first signal.

The output end of the phase compensate circuit 405 is connected with the second isolation circuit 407, and the phase compensation circuit is configured to perform phase compensation on the isolated and power amplified first signal.

The first isolation circuit 406 is configured to isolate the output end of the amplification circuit to isolate the interference of the downstream circuit of the amplification circuit to the amplification circuit.

It could be understood that, the impedance matching circuit 403 may include elements such as resistors and capacitors, and be used for performing impedance matching in response to input impedance and/or output impedance and/or an inter-stage impedance of the amplifier 404. Adjustment of the amplification factor of the amplifier 404 can be realized.

In the embodiments of the disclosure, the input resistance of the impedance matching circuit that adjusts the amplifier through the first sub-control signal or an adjustment resistance between the input end and the output end of the amplifier can realize the adjustment to the gain of the amplifier, so that the power output by the amplifier can meet the power demand.

In some possible embodiments, the amplifier assembly may further include controllers connected to the adder 402, the impedance matching circuit 403 and the phase compensation circuit 405, respectively. The controllers are configured to generate a first control signal, a first sub-control signal, and a second sub-control signal based on a preset phase shift angle. The first control signal is configured to control the adder 402, the first sub-control signal is configured to control the gain of the amplifier 404, and the second sub-control signal is configured to control the phase compensation angle of the phase compensation circuit 405.

In some possible embodiments, the phase compensation circuit includes at least one of an inductor, a capacitor and a switching tube.

Here, the switching tube refers to a semiconductor device that can be used for switching. For example, the switching tube may be a triode or a metal-oxide-semiconductor field-effect transistor (MOSET).

It could be understood that, the voltage on the capacitor cannot change abruptly, and the current phase on the capacitor is 90 degrees ahead of the voltage phase. The current on the inductor cannot change abruptly, and the voltage phase on the inductor is 90 degrees ahead of the current phase. Based on this, in order to realize phase compensation, a phase compensation circuit can be constructed by combining inductors and capacitors in series and parallel. At the same time, by connecting the capacitor or inductor and the switching tube in series in the phase compensation circuit, the inductive reactance of the inductor or the capacitive reactance of the capacitor in the phase compensation circuit can be changed, so that different switching tubes can be turned on or off for different compensation phases.

In some possible embodiments, the amplifier may be a differential amplifier. In other embodiments, the amplifier may also be a single-ended input amplifier, and in this case the signal output by the adder is a single-ended signal, instead of differential signal.

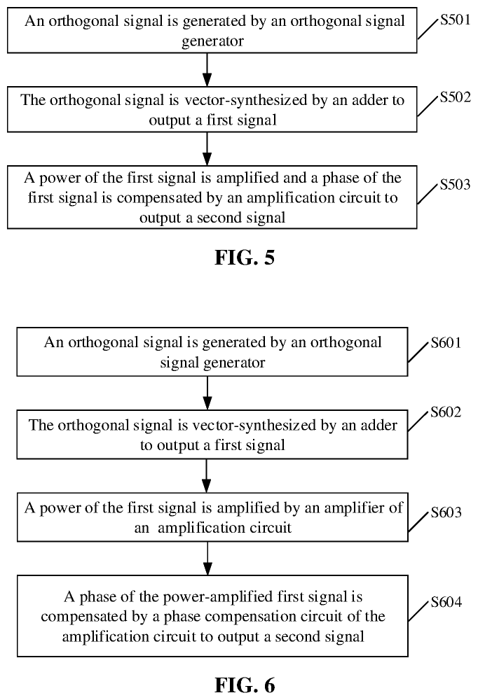

On the basis of the above embodiments, the embodiments of the disclosure further provide a phase shifting method. As shown in FIG. 5, the method includes the following operations.

In S501, an orthogonal signal is generated by an orthogonal signal generator.

In S502, the orthogonal signal is vector-synthesized by an adder to output a first signal.

In S503, a power of the first signal is amplified and a phase of the first signal is compensated by an amplification circuit to output a second signal.

FIG. 6 is an implementation flowchart of another phase shifting method provided by the embodiments of the disclosure. As shown in FIG. 6, the method includes the following operations.

In S601: an orthogonal signal is generated by an orthogonal signal generator.

In S602, the orthogonal signal is vector-synthesized by an adder to output a first signal.

In S603, a power of the first signal is amplified by an amplifier of an amplification circuit.

In S604, a phase of the power-amplified first signal is compensated by a phase compensation circuit of the amplification circuit to output a second signal.

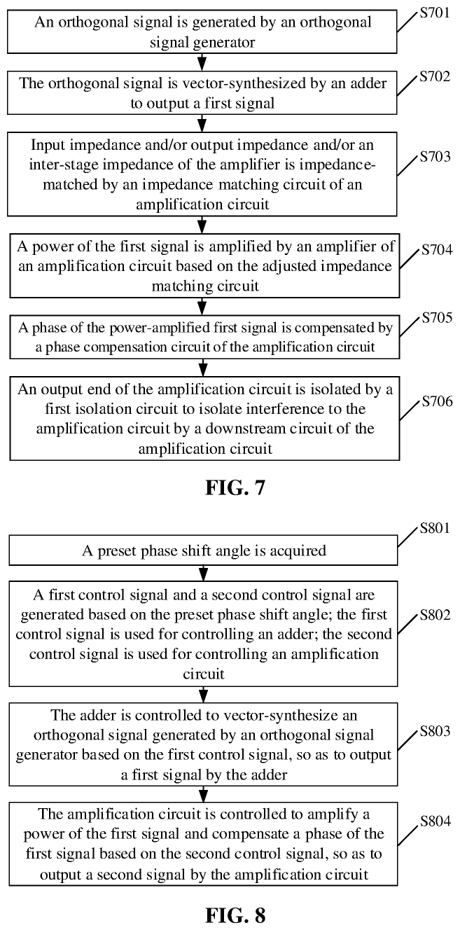

FIG. 7 is an implementation flowchart of yet another phase shifting method provided by the embodiments of the disclosure. As shown in FIG. 7, the method includes the following operations.

In S701: an orthogonal signal is generated by an orthogonal signal generator.

In S702, the orthogonal signal is vector-synthesized by an adder to output a first signal.

In S704, a power of the first signal is amplified by an amplifier of an amplification circuit.

In S705, a phase of the power-amplified first signal is compensated by a phase compensation circuit of the amplification circuit.

In S706, an output end of the amplification circuit is isolated by a first isolation circuit to isolate interference to the amplification circuit by a downstream circuit of the amplification circuit.

FIG. 8 is an implementation flowchart of yet another phase shifting method provided by embodiments of the disclosure. As shown in FIG. 8, the method can be used for a controller, and includes the following operations.

In S801, a preset phase shift angle is acquired.

In S802, a first control signal and a second control signal are generated based on the preset phase shift angle; the first control signal is configured to control an adder, and the second control signal is configured to control an amplification circuit.

In S803, the adder is controlled to vector-synthesize an orthogonal signal generated by an orthogonal signal generator based on the first control signal, so as to output a first signal by the adder.

In S804, the amplification circuit is controlled to amplify a power of the first signal and compensate a phase of the first signal based on the second control signal, so as to output a second signal by the amplification circuit.

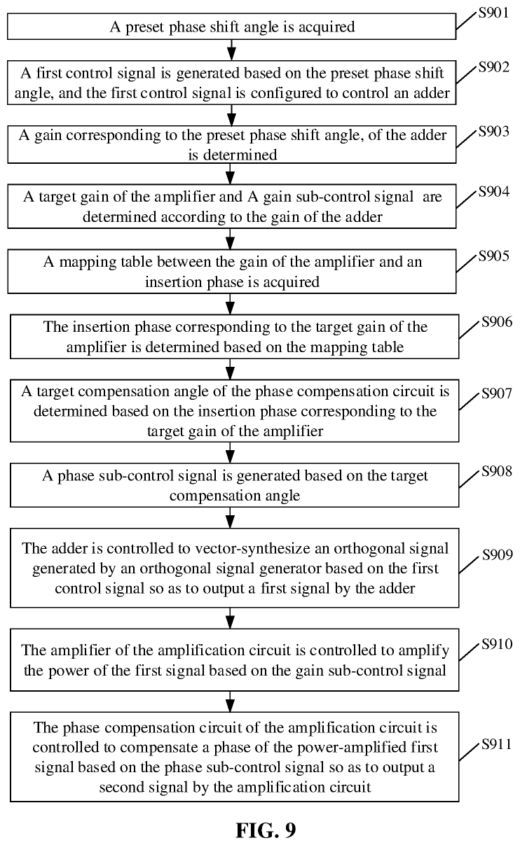

FIG. 9 is an implementation flowchart of another phase shifting method provided by the embodiments of the disclosure. As shown in FIG. 9, the method includes the following operations.

In S901, a preset phase shift angle is acquired.

In S902, a first control signal is generated based on the preset phase shift angle, and the first control signal is configured to control an adder.

It could be understood that, the first control signal is determined according to the preset phase shift angle. The first control signal may include a sub-control signal for controlling the polarity of an orthogonal signal and a sub-control signal for controlling the amplitude of the orthogonal signal.

In S903, a gain, corresponding to the preset phase shift angle, of the adder is determined.

It could be understood that, the adder has different gains for different phase shift angles. For example, when the phase shift angle is 30 degrees, the corresponding gain of the adder is 20. When the phase shift angle is 50 degrees, the corresponding gain of the adder may be 30.

In one possible embodiment, there may be a certain corresponding relationship between the phase shift angle and the gain of the adder. That is, a gain mapping table between the phase shift angle and the gain of the adder may be formed in advance, and then the gain, corresponding to the preset phase shift angle, of the adder may be directly determined according to the gain mapping table.

In S904, a target gain of the amplifier and a gain sub-control signal are determined according to the gain of the adder.

Here, since the output power of the amplifier assembly needs to meet the power output requirement, the target gain of the amplifier can be determined according to the power output requirement when the gain of the adder of the amplifier assembly is determined.

It could be understood that, after determining the target gain of the amplifier, the gain sub-control signal can be generated directly according to the target gain of the amplifier.

In S905, a mapping table between the gain of the amplifier and an insertion phase is acquired.

It could be understood that, the mapping table between the gain of the amplifier and the insertion phase can be obtained through experiments or can be obtained directly through the data sheet of the amplifier.

In S906, the insertion phase corresponding to the target gain of the amplifier is determined based on the mapping table.

In S907, a target compensation angle of the phase compensation circuit is determined based on the insertion phase corresponding to the target gain of the amplifier.

In one possible embodiment, a target compensation angle of the phase compensation circuit may be the insertion phase corresponding to the gain of the amplifier.

In S908, a phase sub-control signal is generated based on the target compensation angle.

In S909, the adder is controlled to vector-synthesize an orthogonal signal generated by an orthogonal signal generator based on the first control signal so as to output a first signal by the adder.

In S910, the amplifier of the amplification circuit is controlled to amplify the power of the first signal based on the gain sub-control signal.

In S911, the phase compensation circuit of the amplification circuit is controlled to compensate a phase of the power-amplified first signal based on the phase sub-control signal so as to output a second signal by the amplification circuit.

In the embodiments of the disclosure, the insertion phase corresponding to the gain of the amplifier is determined through the mapping table between the gain of the amplifier and the insertion phase. The target compensation angle of the phase compensation circuit is determined based on the insertion phase corresponding to the gain of the amplifier. A phase sub-control signal is generated based on the target compensation angle. The phase compensation circuit in the amplification circuit is controlled based on the phase sub-control signal, to compensate the phase of the power-amplified first signal, so as to output the second signal by the amplification circuit. The phase shift of the second signal is closer to the preset phase shift angle, that is, the phase shift accuracy is higher.

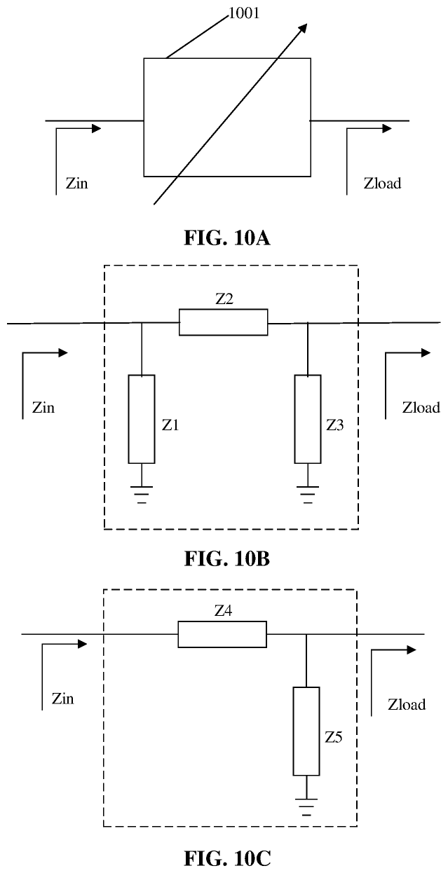

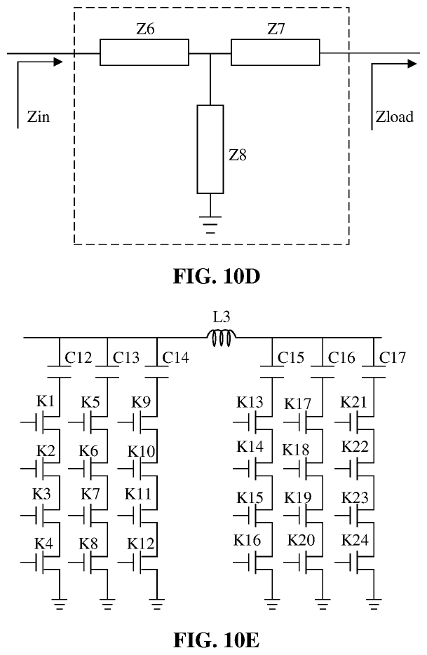

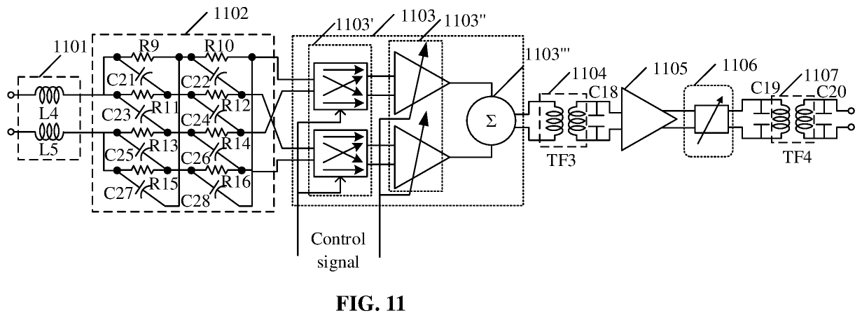

FIG. 10A is a component schematic diagram of a phase compensation unit provided by the embodiments of the disclosure. As shown in FIG. 10A, the phase compensation unit may be an adjustable matching network 1001. The adjustable matching network 1001 is reasonably designed, so that Zin can be adjusted to the impedance point matching the load impedance (Zload) of the adjustable matching network 1001 by tuning the adjustable matching network 1001, without adding additional matching network elements.

FIG. 10B is a schematic diagram of the component structure of a phase compensation unit provided by the embodiments of the disclosure. As shown in FIG. 10B, Z1 is connected across the input end and the grounding end of the phase compensation unit; One end of Z2 is connected to the input end of the phase compensation unit, the other end of Z2 is connected to one end of Z3, and the other end of Z3 is connected to the grounding end. The common node of Z2 and Z3 is the output end of the phase compensation unit.

FIG. 10C is a schematic diagram of the component structure of another phase compensation unit provided by the embodiments of the disclosure. As shown in FIG. 10C, a series branch formed by connecting Z4 and Z5 in series is connected cross the input end and the grounding end of the phase compensation unit, and the common node of Z4 and Z5 is used as the output end of the phase compensation unit.

FIG. 10D is a schematic diagram of the component structure of yet another phase compensation unit provided by the embodiments of the disclosure. As shown in FIG. 10D, a series branch formed by connecting Z6 and Z7 in series is connected cross the input end and the output end of the phase compensation unit, one end of Z8 is connected to the grounding end, and the other end of Z8 is connected to the common node of Z6 and Z7.

Here, Z1, Z2, Z3, Z4, Z5, Z6 Z7 and Z8 may be inductors, capacitors, resistors and transmission lines, may have a fixed reactance value or a variable reactance value, at least one of which has a variable reactance value. Herein, the variable reactance may be realized by, but not limited to electrically modulated varactor, variable capacitor array, switching inductor or resistor array.

FIG. 10E is a circuit diagram of a phase compensation unit provided by the embodiments of the disclosure. As shown in FIG. 10E, there are the third inductor L3, the twelfth capacitor C12 to the seventeenth capacitor C17, the first switch K1 to the twenty-fourth switch K24, in which C12 and K1 to K4 are connected in series to form the first series branch, C13 and K5 to K8 are connected in series to form the second series branch; C14 and K9 to K12 are connected in series to form the third series branch; C15 and K13 to K16 are connected in series to form the fourth series branch; C16 and K17 to K20 are connected in series to form the fifth series branch; C17 and K21 to K24 are connected in series to form the sixth series branch. The first parallel branch formed by connecting the first to third series branches in parallel is connected cross the input end and the grounding end of the phase compensation unit; L3 is connected cross the input end and the output end of the phase compensation unit. The second parallel branch formed by connecting the fourth to sixth series branches in parallel is connected cross the output end and the grounding end of the phase compensation unit. It can be seen that the capacitance value connected to the matching network can be changed by switching the switch on and off, thereby changing the impedance of the matching network to achieve the function of adjustable matching.

FIG. 11 is a component circuit diagram of an active phase shifter provided by the embodiments of the disclosure. As shown in FIG. 11, the active filter includes an inter stage matching network (IMN) 1101, PPF 1102, an analog adder 1103, a transformer TF3 1104, the eighteenth capacitor C18, an amplifier 1105, a phase compensation circuit 1106, the nineteenth capacitor C19, a transformer TF4 1107, and the twentieth capacitor C20 that are connected in sequence. A differential radio frequency signal with constant amplitude is input to the input end of the IMN 1101, the input differential radio frequency signal with constant amplitude is network matched by the IMN 1101, and the network matched differential radio frequency signal with constant amplitude is input to the PPF 1102. By the PPF 1102, four orthogonal signals (two positive output ends I+, Q+, and two negative output ends I−, Q−) with the same amplitude and 90-degree phase spacing are generated. The four orthogonal signals with the same amplitude and 90-degree phase spacing are input to the analog adder 1103. The four orthogonal signals with the same amplitude and 90-degree phase spacing are vector-synthesized by the analog adder 1103 in response to a control signal from the outside, The first in-phase orthogonal signal with equal phase shift is output to the TF3 1104, and then isolated by the TF3 1104. The isolated first in-phase orthogonal signal is output to the amplifier 1105, and then the power thereof is amplified by the amplifier 1105, so as to output the isolated and power-amplified first in-phase orthogonal signal to the phase compensation circuit 1106. After the phase compensation by the phase compensation circuit, the phase-compensated in-phase orthogonal signal is obtained. The phase-compensated in-phase orthogonal signal is isolated by the TF4 1107, so as to output a second in-phase orthogonal signal.

Here, C18 is connected cross the two input ends of the amplifier 1105, and is configured to remove the electromagnetic interference. C19 and C20 are connected cross the two input ends and two output ends of the transformer TF4 1107, respectively, and are configured to remove the electromagnetic interference generated by TF4 1107.

Here, the IMN 1101 includes a fourth inductor L4 and a fifth inductor L5. L4 and L5 are respectively connected in series to the input end and the input end of the PPF 1102. The PPF 1102 is a two-order RC filter. The analog adder 1103 includes an orthogonal path selecting unit 1103′, a variable gain amplifier (VGA) 1103″ and an adder 1103′″ that are connected in sequence.

It could be understood that the two-order RC filter includes eight resistors R9 to R16 and eight capacitors C12 to C28. Herein, a series branch formed by connecting R9 and R10 in series is connected between the input end and the output end (I+) of the two-order RC filter; a series branch formed by connecting R11 and R12 in series is connected between the input end and the output end (Q+) of the two-order RC filter; a series branch formed by connecting R13 and R14 in series is connected between the input end and the third output end (I−) of the two-order RC filter; a series branch formed by connecting R15 and R16 in series is connected between the input end and the fourth output end (Q−) of the two-order RC filter. C21 is connected across both ends of R11, and the positive electrode of C21 is connected to the input end. The negative electrode of C22 is connected to the output end, and the positive electrode of C22 is connected to the common node of R9 and R10. The positive electrode of C23 is connected to the input end, and the negative electrode of C23 is connected to the common node of R13 and R14. The negative electrode of C24 is connected to the third output end, and the positive electrode of C24 is connected to the common node of R11 and R12. C25 is connected across both ends of R15, and the positive electrode of C25 is connected to the input end. The negative electrode of C26 is connected to the fourth output end, and the positive electrode of C26 is connected to the common node of R13 and R14. The positive electrode of C27 is connected to the input end, and the negative electrode of C27 is connected to the common node of R9 and R10. The negative electrode of C28 is connected to the output end, and the positive electrode of C28 is connected to the common node of R15 and R16.

The above description of various embodiments tends to emphasize the differences among them, and the same or similarities thereof can be referred to each other, which are not be repeated herein for the sake of brevity.

The embodiments of the disclosure also provide a computer program product including a non-transient computer-readable storage medium storing a computer program, in which the computer program allows a computer to execute part or all of the operations of any the phase shifting method as described in the above method embodiment.

The methods disclosed in various method embodiments provided by the disclosure may be combined arbitrarily without conflict to obtain new method embodiments.

The features disclosed in various product embodiments provided by the disclosure may be combined arbitrarily without conflict to obtain new product embodiments.

The features disclosed in various method or phase shifters provided by the disclosure may be combined arbitrarily without conflict to obtain new method or equipment embodiments.

The embodiments of the disclosure are described above in combination with the drawings. However, the disclosure is not limited to the above embodiments. The above embodiments are merely illustrative and not restrictive. Many variants can be obtained by those skilled in the art under the teachings provided by this disclosure without departing from the spirit of this disclosure and protection scope of the claims, all of which fall within the protection of this application.

In the embodiments of the disclosure, the orthogonal signal is generated by the orthogonal signal generator, and is vector-synthesized by the adder performs to output the first signal. The power of the first signal is amplified and the phase of the first signal is compensated by the amplification circuit to output the second signal. That is, the amplification circuit can perform power amplification and phase compensation on the first signal based on different control signals, thereby reducing the influence on the phase shifting accuracy caused by the change of the insertion phase of the amplification circuit under different gains.

1. An amplifier assembly comprising an orthogonal signal generator, an adder, and an amplification circuit;
an output end of the orthogonal signal generator being connected with an input end of the adder, and the orthogonal signal generator being configured to generate an orthogonal signal;
an output end of the adder being connected with an input end of the amplification circuit, and the adder being configured to vector-synthesize the orthogonal signal to output a first signal; and
the amplification circuit being configured to amplify a power of the first signal and compensate a phase of the first signal to output a second signal.

2. The amplifier assembly according to claim 1, wherein
the amplification circuit comprises an amplifier and a phase compensation circuit;
the amplifier is configured to amplify the power of the first signal;
the phase compensation circuit is configured to compensate the phase of the first signal.

3. The amplifier assembly according to claim 1, wherein an input end of the phase compensation circuit is connected with the output end of the adder and an output end of the phase compensation circuit is connected with the amplifier to output the phase-compensated first signal.

4. The amplifier assembly according to claim 1, wherein an input end of the amplifier is connected with the output end of the adder and an output end of the amplifier is connected with an input end of the phase compensation circuit to output the amplified first signal.

5. The amplifier assembly according to claim 1, wherein a compensation phase of the phase compensation circuit is adjustable based on a gain and/or an output power of the amplifier.

6. The amplifier assembly according to claim 1, wherein the phase compensation circuit has a compensation structure of at least one of “pi (π) type”, “T type” and “L type”.

7. The amplifier assembly according to claim 1, wherein the amplifier assembly further comprises a first isolation circuit having an input end connected with an output end of the amplification circuit, and being configured to isolate the output end of the amplification circuit to isolate an interference of a downstream circuit of the amplification circuit to the amplification circuit.

8. The amplifier assembly according to claim 1, wherein the amplifier assembly further comprises a second isolation circuit, an input end of the second isolation circuit is connected with the output end of the adder, and an output end of the second isolation circuit is connected with the input end of the amplification circuit; and
the second isolation circuit is configured to isolate the output of the adder.

9. The amplifier assembly according to claim 2, wherein the amplification circuit further comprises an impedance matching circuit;
the impedance matching circuit is configured to impedance-match an input impedance and/or an output impedance and/or an inter-stage impedance of the amplifier.

10. The amplifier assembly according to claim 2, wherein the phase compensation circuit comprises at least one of an inductor, a capacitor and a switching tube.

11. The amplifier assembly according to claim 1, wherein the amplifier is a differential amplifier.

12. A phase shifting method comprising:
generating an orthogonal signal by an orthogonal signal generator;
vector-synthesizing the orthogonal signal by an adder to output a first signal; and
amplifying a power of the first signal and compensating a phase of the first signal by an amplification circuit to output a second signal.

13. The method according to claim 12, wherein the amplification circuit comprises an amplifier and a phase compensation circuit;
correspondingly, the amplifying a power of the first signal and compensating a phase of the first signal by an amplification circuit to output a second signal comprises
amplifying the power of the first signal by the amplifier; and
compensating the phase of the power-amplified first signal by the phase compensation circuit to output the second signal.

14. The method of according to claim 12, further comprising:
isolating an output end of the amplification circuit through a first isolation circuit to isolate an interference of a downstream circuit of the amplification circuit to the amplification circuit.

15. The method of according to claim 12, further comprising:
isolating an output end of the adder through a first isolation circuit.

16. The method of according to claim 13, wherein the amplification circuit further comprises an impedance matching circuit;
the impedance matching circuit performs an impedance matching on an input impedance and/or an output impedance and/or an inter-stage impedance of the amplifier.

17. A phase shifting method comprising:
acquiring a preset phase shift angle;
generating a first control signal and a second control signal based on the preset phase shift angle, wherein the first control signal is used for controlling an adder, and the second control signal is used for controlling an amplification circuit;
vector-synthesizing an orthogonal signal generated by an orthogonal signal generator through controlling the adder based on the first control signal, to output a first signal by the adder; and
amplifying a power of the first signal and compensating a phase of the first signal through controlling the amplification circuit based on the second control signal, to output a second signal by the amplification circuit.

18. The method of according to claim 17, wherein the second control signal comprises a gain sub-control signal and a phase sub-control signal; the gain sub-control signal is used for controlling a gain of an amplifier of the amplification circuit; the phase sub-control signal is used for controlling an phase compensation angle of a phase compensation circuit of the amplification circuit;
wherein the generating the second control signal based on the preset phase shift angle comprises:
determining a gain corresponding to the preset phase shift angle of the adder;
determining a target gain of the amplifier and the gain sub-control signal according to the gain of the adder;
acquiring a mapping table between the gain of the amplifier and an insertion phase;
determining the insertion phase corresponding to the target gain based on the mapping table;
determining a target compensation angle of the phase compensation circuit based on the insertion phase corresponding to the target gain of the amplifier; and
generating the phase sub-control signal based on the target compensation angle;
correspondingly, wherein the amplifying a power of the first signal and compensating a phase of the first signal based on the second control signal to output a second signal by the amplification circuit comprises: controlling the amplifier to amplify the power of the first signal based on the gain sub-control signal; and
controlling the phase compensation circuit to compensate the phase of the power-amplified first signal based on the phase sub-control signal to output the second signal by the amplification circuit.

19. A computer program product comprising a computer-readable code, wherein a controller of an amplifier assembly performs operations of the phase shifting method of claim 17, when the computer-readable code is executed in the amplifier assembly.
